(19) United States
(12) Patent Application Publication
(10) Pub. No.: US 2026/0068379 A1
(43) Pub. Date: Mar. 5, 2026

(54) DISPLAY PANEL AND DISPLAY DEVICE

(71) Applicant: Beijing Visionox Technology Co., Ltd., Beijing (CN)

(72) Inventors: Enqing GUO, Beijing (CN); Cuili GAI, Beijing (CN); Jianjun LU, Beijing (CN)

(73) Assignee: Beijing Visionox Technology Co., Ltd., Beijing (CN)

(21) Appl. No.: 19/383,729

(22) Filed: Nov. 9, 2025

(30) Foreign Application Priority Data
Nov. 11, 2024 (CN) 202411606845.5

(51) Int. Cl. H10H 29/32; H10D 86/40; H10D 86/60; H10H 29/49; H10H 29/855

(52) U.S. Cl. CPC H10H 29/32; H10D 86/423; H10D 86/441; H10D 86/481; H10D 86/60; H10H 29/49; H10H 29/8552

(57) ABSTRACT

The embodiments of the present application disclose a display panel and a display device. The display panel includes: a substrate, a plurality of conductive layers stacked on a side of the substrate, and at least one pixel circuit including a driving transistor and a first capacitor; where the plurality of conductive layers stacked on the side of the substrate include a first conductive layer and a second conductive layer, and the second conductive layer is located on a side of the first conductive layer away from the substrate, enhancing the stability of a screen, and thus improving the display effect.

### CROSS-REFERENCE TO RELATED APPLICATIONS

The present application claims priority to the Chinese Patent Application 202411606845.5, filed on Nov. 11, 2024, and the entire contents of the aforementioned application are hereby incorporated by reference in its entirety.

### FIELD

The embodiments of the present application relate to the field of display, and in particular to a display panel and a display device.

### BACKGROUND

With the development of display technology, there are increasingly high requirements for the display performance of display panels.

At present, the display panels have poor display effects and cannot meet the high-quality display requirements.

### SUMMARY

The embodiments of the present application provide a display panel and a display device, which can improve the display effect of the display panel.

According to an embodiment of the present application, a display panel is provided. The display panel includes:
a substrate;
a plurality of conductive layers stacked on a side of the substrate;
at least one pixel circuit including a driving transistor and a first capacitor;
where the plurality of conductive layers include a first conductive layer and a second conductive layer, the second conductive layer is located on a side of the first conductive layer away from the substrate, a first plate of the first capacitor is located in the first conductive layer, a second plate of the first capacitor is located in the second conductive layer, and the second plate of the first capacitor is connected to a first gate of the driving transistor; and an active layer located on a side of the second conductive layer away from the substrate.

According to another embodiment of the present application, a display device is provided. The display device includes a display panel according to any of the embodiments of the present application.

According to the embodiments of the present application, the plurality of conductive layers stacked on the side of the substrate include the first conductive layer and the second conductive layer, the second conductive layer is located on the side of the first conductive layer away from the substrate, the active layer is disposed on the side of the second conductive layer away from the substrate, the first plate of the first capacitor is located in the first conductive layer, and the second plate of the first capacitor is located in the second conductive layer, and the first capacitor is located below the driving transistor, thereby enabling the first plate of the first capacitor to provide bottom light-shielding for the driving transistor. This helps to mitigate adverse effects of light irradiation on the driving transistor, enhances the stability of a screen, and thus improves the display effect.

### BRIEF DESCRIPTION OF THE DRAWINGS

FIG. 1 is a schematic diagram of a planar structure of a display panel according to an embodiment of the present application;

FIG. 2 is a schematic diagram of a cross-sectional structure of a display panel according to an embodiment of the present application;

FIG. 3 is a schematic diagram of a planar structure of another display panel according to an embodiment of the present application;

FIG. 4 is a schematic diagram of a cross-sectional structure of another display panel according to an embodiment of the present application;

FIG. 5 is a schematic diagram of a planar structure of another display panel according to an embodiment of the present application;

FIG. 6 is a schematic diagram of a cross-sectional structure of another display panel according to an embodiment of the present application;

FIG. 7 is a schematic structural diagram of a pixel circuit according to an embodiment of the present application;

FIG. 8 is a schematic diagram of a layout structure of a first capacitor according to an embodiment of the present application;

FIG. 9 is a schematic diagram of a planar structure of another display panel according to an embodiment of the present application;

FIG. 10 is a schematic diagram of a planar structure of another display panel according to an embodiment of the present application;

FIG. 11 is a schematic diagram of a cross-sectional structure of another display panel according to an embodiment of the present application;

FIG. 12 is a schematic diagram of a cross-sectional structure of another display panel according to an embodiment of the present application;

FIG. 13 is a schematic diagram of a cross-sectional structure of another display panel according to an embodiment of the present application;

FIG. 14 is a schematic diagram of a planar structure of another display panel according to an embodiment of the present application;

FIG. 15 is a schematic diagram of a planar structure of another display panel according to an embodiment of the present application;

FIG. 16 is a schematic diagram of a cross-sectional structure of another display panel according to an embodiment of the present application;

FIG. 17 is a schematic diagram of a cross-sectional structure of another display panel according to an embodiment of the present application;

FIG. 18 is a schematic diagram of a planar structure of another display panel according to an embodiment of the present application;

FIG. 19 is a schematic diagram of a planar structure of another display panel according to an embodiment of the present application;

FIG. 20 is a schematic diagram of a cross-sectional structure of another display panel according to an embodiment of the present application;

FIG. 21 is a schematic diagram of a planar structure of another display panel according to an embodiment of the present application;

FIG. 22 is a schematic diagram of a cross-sectional structure of another display panel according to an embodiment of the present application;

FIG. 23 is a schematic structural view of another pixel circuit according to an embodiment of the present application;

FIG. 24 is a schematic diagram of a planar structure of another display panel according to an embodiment of the present application;

FIG. 25 is a schematic diagram of a cross-sectional structure of another display panel according to an embodiment of the present application; and

FIG. 26 is a schematic structural view of a display device according to an embodiment of the present application.

### DETAILED DESCRIPTION OF THE EMBODIMENTS

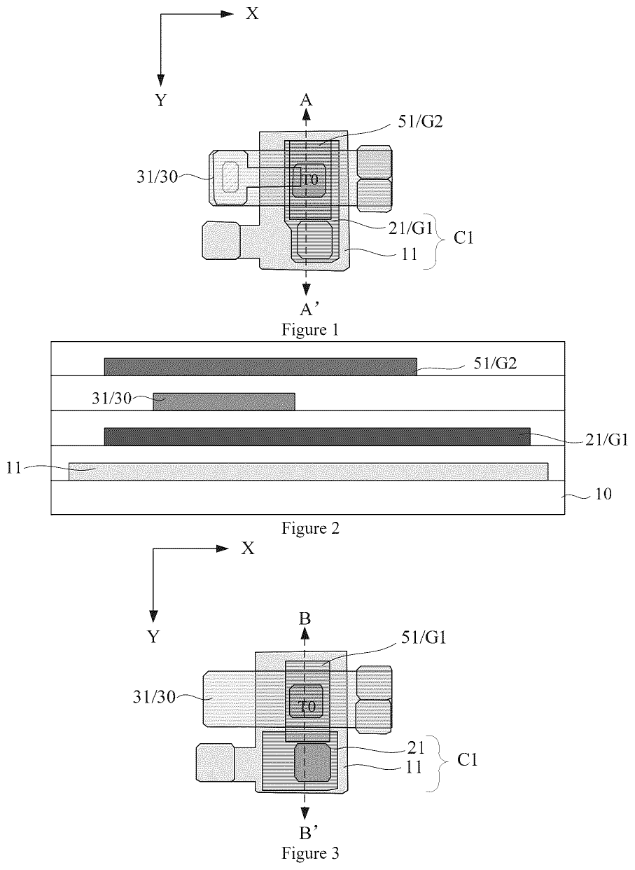

FIG. 1 is a schematic diagram of a planar structure of a display panel according to an embodiment of the present application, and FIG. 2 is a schematic diagram of a cross-sectional structure of a display panel according to an embodiment of the present application, and specifically, a cross-sectional structure of the display panel shown in FIG. 1 taken along a sectional line AA′. Referring to FIG. 1 and FIG. 2, the display panel according to this embodiment includes:
a substrate 10;
a plurality of conductive layers stacked on a side of the substrate 10;
at least one pixel circuit including a driving transistor T0 and a first capacitor C1;
where the plurality of conductive layers include a first conductive layer and a second conductive layer, the second conductive layer is located on a side of the first conductive layer away from the substrate 10, a first plate 11 of the first capacitor C1 is located in the first conductive layer, a second plate 21 of the first capacitor C1 is located in the second conductive layer, and the second plate 21 of the first capacitor C1 is connected to a first gate G1 of the driving transistor T0; and
an active layer 30 located on a side of the second conductive layer away from the substrate 10.

Specifically, the substrate 10 serves to protect and support the display panel. The substrate 10 may be a flexible substrate formed of materials such as polyimide (PI), polyethylene naphthalate (PEN), or polyethylene terephthalate (PET), or a rigid substrate formed of materials such as glass. The plurality of conductive layers are disposed on the side of the substrate 10 and are isolated from each other by insulating layers. A plurality of pixel circuits are formed in the display panel and are used for driving light-emitting elements to emit light. The pixel circuit includes the driving transistor T0 and the first capacitor C1, the first capacitor C1 being used for storing a gate voltage of the driving transistor T0.

The first gate G1 of the driving transistor T0 is connected to the second plate 21 of the first capacitor C1, meaning that the first gate G1 of the driving transistor T0 and the second plate 21 of the first capacitor C1 may be multiplexed on the same layer or may be disposed on separate layers, and then connected via a via. As an example, as shown in FIG. 1 and FIG. 2, the driving transistor T0 may be of a bottom gate driving type, that is, the first gate G1 of the driving transistor T0 serves as a control electrode. In this embodiment, the second plate 21 of the first capacitor C1 is multiplexed as the first gate G1 of the driving transistor T0, and the second plate 21 of the first capacitor C1 serves as a bottom gate of the driving transistor T0. A first metal line 51 is provided on a side of the active layer 30 away from the substrate 10, the first metal line 51 is configured for a second gate G2 of the driving transistor T0, and the second gate G2 serves as a top gate of the driving transistor T0.

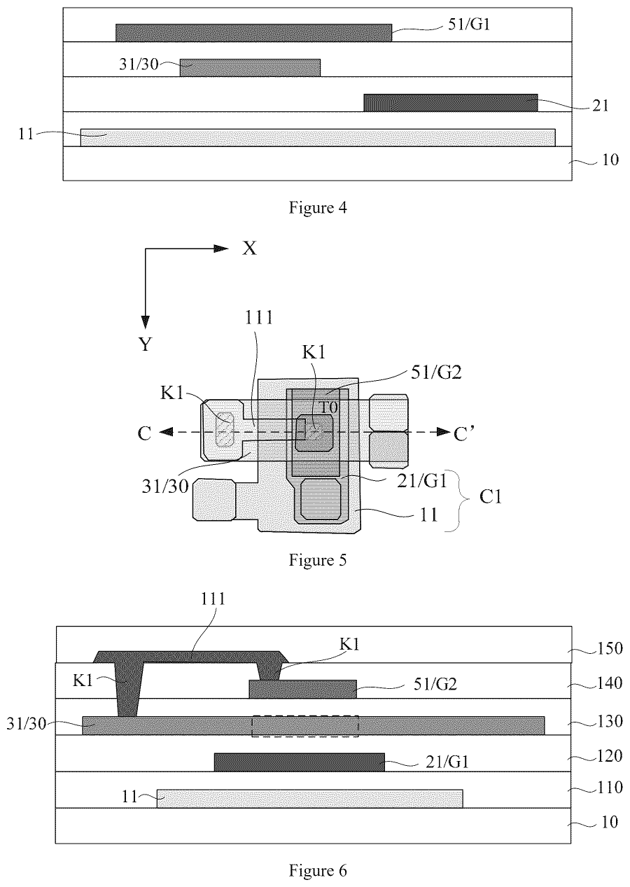

As another example, the driving transistor T0 may also be of a top gate driving type. FIG. 3 is a schematic diagram of a planar structure of another display panel according to an embodiment of the present application, and FIG. 4 is a schematic diagram of a cross-sectional structure of another display panel according to an embodiment of the present application, and specifically, a cross-sectional structure of the display panel shown in FIG. 3 taken along a sectional line BB′. Referring to FIG. 3 and FIG. 4, the driving transistor T0 is not provided with the second gate G2, but only with the first metal line 51, Here, the first metal line 51 serves as the first gate G1 of the driving transistor TO, and the first gate G1 of the driving transistor T0 is connected to the second plate 21 of the first capacitor C1 via a via.

According to the embodiments of the present application, the plurality of conductive layers stacked on the side of the substrate 10 include the first conductive layer and the second conductive layer, the second conductive layer is located on the side of the first conductive layer away from the substrate 10, the active layer 30 is disposed on the side of the second conductive layer away from the substrate, the first plate 11 of the first capacitor C1 is located in the first conductive layer, and the second plate 21 is located in the second conductive layer, and the first capacitor C1 is located below the driving transistor T0, thereby enabling the first plate 11 of the first capacitor C1 to provide bottom light-shielding for the driving transistor T0. This helps to mitigate adverse effects of light irradiation on the driving transistor T0, enhances the stability of a screen, and thus improves the display effect.

The following describes a dual-gate structure and a single-gate structure of the driving transistor T0, respectively.

Further referring to FIG. 1 and FIG. 2, the first gate G1 of the driving transistor TO is located in the second conductive layer, and the second plate 21 of the first capacitor C1 is multiplexed as the first gate G1 of the driving transistor T0. The first plate 11 and the second plate 21 of the first capacitor C1 are respectively located in different conductive layers. For example, the first plate 11 of the first capacitor C1 is located in the first conductive layer, and the second plate 21 of the first capacitor C1 is located in the second conductive layer. An orthographic projection of the first plate 11 of the first capacitor C1 on the substrate 10 at least partially overlaps an orthographic projection of the second plate 21 of the first capacitor C1 on the substrate 10, and an overlapping region therebetween constitutes effective capacitance of the first capacitor C1. The active layer 30 includes a first active layer 31 extending in a first direction X, and a channel region of the driving transistor T0 is located in the first active layer 31. A source region and a drain region of the driving transistor T0 are respectively located on two sides of the channel region, and the first gate G1 of the driving transistor T0 overlaps the channel region of the driving transistor T0, that is, the orthographic projection of the second plate 21 of the first capacitor C1 on the substrate 10 at least partially covers an orthographic projection of the channel region of the driving transistor T0 on the substrate 10.

In one embodiment, the orthographic projection of the first plate 11 of the first capacitor C1 on the substrate 10 at least partially covers the orthographic projection of the channel region of the driving transistor T0 on the substrate 10. In this way, the first plate 11 located in the first conductive layer may serve as a lower plate of the first capacitor C1 and also serve as a light-shielding layer for the driving transistor T0, to save layout space and improve layout space utilization. This also avoids variations in the electrical performance of the driving transistor T0 caused by light irradiation, which helps to improve the reliability of the pixel circuit and thus improves the reliability of the screen.

In one embodiment, a material of the active layer 30 includes a metal oxide, which helps to reduce a leakage current of the pixel circuit.

In one embodiment, the plurality of conductive layers further include a third conductive layer. The third conductive layer is located on the side of the active layer 30 away from the substrate 10, and the second gate G2 of the driving transistor T0 is located in the third conductive layer. The second gate G2 of the driving transistor T0 is connected to a first electrode of the driving transistor T0. An orthographic projection of the second gate G2 of the driving transistor T0 on the substrate 10 at least partially covers the orthographic projection of the channel region of the driving transistor T0 on the substrate 10. The first electrode of the driving transistor T0 may be a source. Here, the first gate G1 of the driving transistor T0 serves as a bottom gate, and the second gate G2 of the driving transistor T0 serves as a top gate. The bottom gate serves as a control electrode to realize the drive control of the driving transistor T0. By using a dual-gate transistor, the control capability of the gates over the channel region can be enhanced, which helps to improve the sub-threshold swing of the driving transistor T0, facilitates grayscale expansion, and enhances display luminance uniformity.

In one embodiment, FIG. 5 is a schematic diagram of a planar structure of another display panel according to an embodiment of the present application, and FIG. 6 is a schematic diagram of a cross-sectional structure of another display panel according to an embodiment of the present application, and specifically, a cross-sectional structure of the display panel shown in FIG. 5 taken along a sectional line CC′. Referring to FIG. 5 and FIG. 6, the plurality of conductive layers further include a fourth conductive layer, the fourth conductive layer is located on a side of the third conductive layer away from the substrate 10, the fourth conductive layer includes a first connection line 111, and the second gate G2 of the driving transistor T0 is connected to the first electrode of the driving transistor T0 via the first connection line 111.

Specifically, the plurality of conductive layers are isolated from each other by insulating layers. For example, a capacitor insulating layer 110 is provided between the first conductive layer and the second conductive layer, a first gate insulating layer 120 is provided between the second conductive layer and the active layer 30, a second gate insulating layer 130 is provided between the active layer 30 and the third conductive layer, an interlayer insulating layer 140 is provided between the third conductive layer and the fourth conductive layer, and a first planarization layer 150 is provided on a side of the fourth conductive layer away from the substrate 10.

The first connection line 111 is located in the fourth conductive layer and is used for connecting the second gate G2 and the first electrode of the driving transistor T0, that is, for connecting the first metal line 51 and the source of the driving transistor T0. For example, the second gate G2 of the driving transistor T0 is connected to one end of the first connection line 111 via a first-type via K1, and the first electrode of the driving transistor T0 is connected to the other end of the first connection line 111 via the first-type via K1. That is, the second gate G2 and the first electrode of the driving transistor T0 are connected in a bridge-crossing manner via the first connection line 111. The first-type via K1 is a via that extends through the interlayer insulating layer 140, or through both the interlayer insulating layer 140 and the second gate insulating layer 130.

In one embodiment, an orthographic projection of the first connection line 111 on the substrate 10 at least partially covers the orthographic projection of the second gate G2 of the driving transistor T0 on the substrate 10, to realize a connection between the first connection line 111 serving as the second gate G2 of the driving transistor T0 and the first electrode of the driving transistor T0.

Referring to FIG. 6, in this embodiment, on the first active layer 31, an area covered by the second gate G2 of the driving transistor T0 serves as the channel region of the driving transistor T0 (the portion within a dashed box on the first active layer 31), and the orthographic projection of the second gate G2 of the driving transistor T0 on the substrate 10 covers the orthographic projection of the channel region of the driving transistor T0 on the substrate 10.

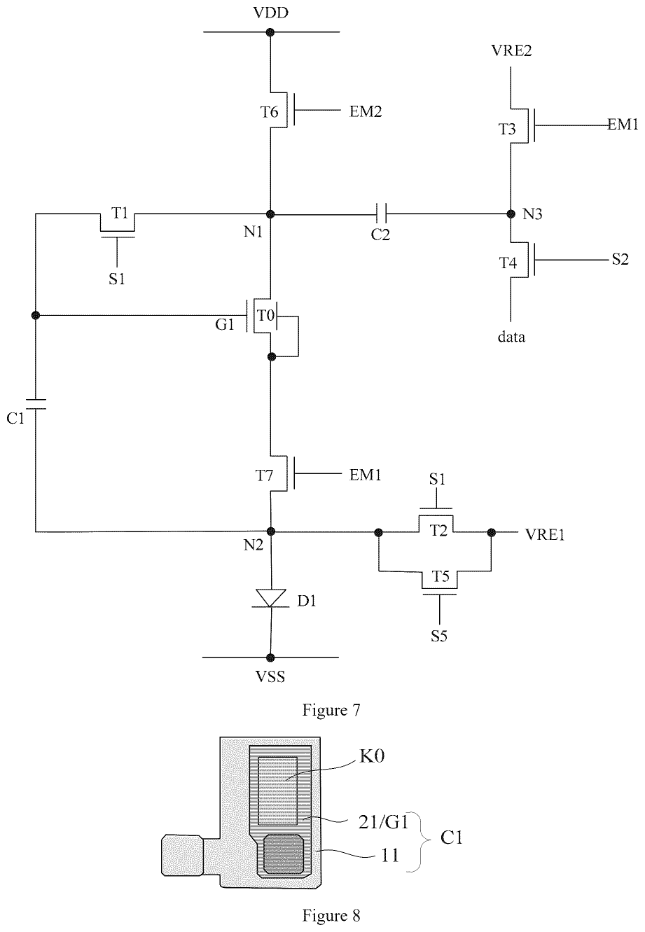

FIG. 7 is a schematic structural diagram of a pixel circuit according to an embodiment of the present application. Referring to FIG. 5 and FIG. 7, on the basis of the above embodiments, the first gate G1 of the driving transistor T0 is connected to the second plate 21 of the first capacitor C1 (here, the second plate 21 of the first capacitor C1 is multiplexed as the first gate G1 of the driving transistor T0). The first plate 11 of the first capacitor C1 is connected to a second node N2, and the first capacitor C1 is used for storing a voltage of the first gate G1 of the driving transistor T0.

FIG. 8 is a schematic diagram of a layout structure of a first capacitor according to an embodiment of the present application. Referring to FIG. 8, on the basis of the above embodiments, in one embodiment, the first plate 11 of the first capacitor C1 includes an aperture region K0, and an overlap between the orthographic projection of the first plate 11 of the first capacitor C1 on the substrate 10 and the orthographic projection of the second plate 21 of the first capacitor C1 on the substrate 10 at least partially covers an orthographic projection of the aperture region K0 on the substrate 10. That is, the first conductive layer at the position of the aperture region K0 on the first plate 11 of the first capacitor C1 is removed to reduce an overlapping area between the first plate 11 of the first capacitor C1 and the second plate 21 of the first capacitor C1.

Specifically, as known from a capacitance calculation formula, a capacitance value of the capacitor is related to the overlapping area of the upper and lower plates. Therefore, by providing the aperture region K0 on the first plate 11 of the first capacitor C1, the capacitance value of the first capacitor C1 can be adjusted to meet different functional requirements of the pixel circuit.

Further referring to FIG. 7, the pixel circuit also includes a first transistor T1 connected between the first gate G1 of the driving transistor T0 and a first node N1 (a second electrode of the driving transistor T0 and a first electrode of the first transistor T1 are connected to the first node N1). A gate of the first transistor T1 is connected to a first scan signal line S1, and the first transistor T1 is used for compensating for a threshold voltage of the driving transistor T0 in response to the first scan signal line S1.

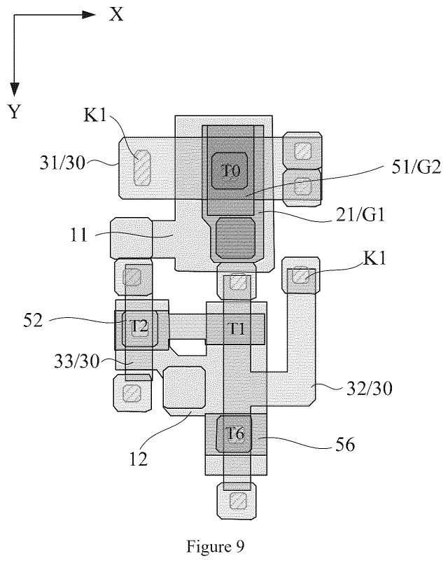

FIG. 9 is a schematic diagram of a planar structure of another display panel according to an embodiment of the present application. Referring to FIG. 7 and FIG. 9, in one embodiment, the active layer 30 further includes a second active layer 32 extending in a second direction Y. The first direction X intersects, and specifically, perpendicularly intersects the second direction Y. The second active layer 32 is in the same layer as, but is not connected to the first active layer 31, and a channel region of the first transistor T1 is located in the second active layer 32.

The channel region of the first transistor T1 is located at an orthographic projection of the gate of the first transistor T1 on the second active layer 32, and the gate of the first transistor T1 is located in the third conductive layer. For example, a second metal line 52 located in the third conductive layer is the gate of the first transistor T1, and on the second active layer 32, an intersection of the second active layer 32 and the second metal line 52 is the channel region of the first transistor T1.

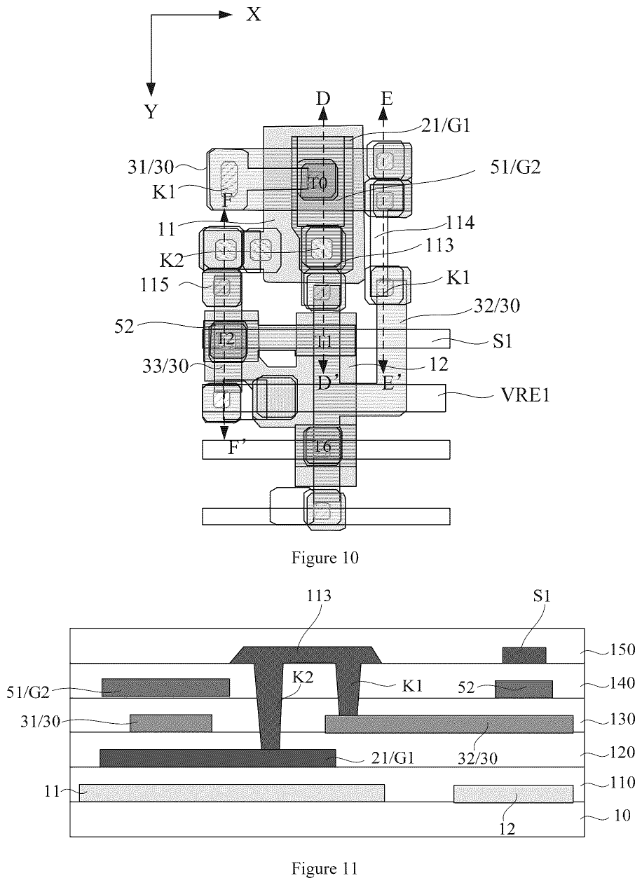

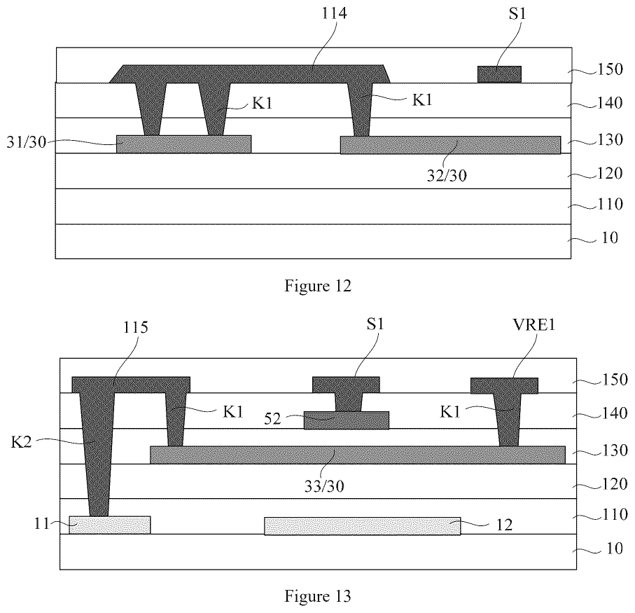

FIG. 10 is a schematic diagram of a planar structure of another display panel according to an embodiment of the present application, FIG. 11 is a schematic diagram of a cross-sectional structure of another display panel according to an embodiment of the present application, and FIG. 12 is a schematic diagram of a cross-sectional structure of another display panel according to an embodiment of the present application, where FIG. 11 specifically shows a cross-sectional structure of the display panel shown in FIG. 10 taken along a sectional line DD′, and FIG. 12 specifically shows a cross-sectional structure of the display panel shown in FIG. 10 taken along a sectional line EE′. Referring to FIG. 10, FIG. 11 and FIG. 12, the fourth conductive layer further includes a third connection line 113 and a fourth connection line 114, the first electrode of the first transistor T1 is connected to the first gate G1 of the driving transistor T0 via the third connection line, and a second electrode of the first transistor T1 is connected to the second electrode of the driving transistor T0 via the fourth connection line 114. The second electrode of the driving transistor T0 may be a drain.

Specifically, the third connection line 113 and the fourth connection line 114 are both located in the fourth conductive layer and extend in the second direction Y. As shown in FIG. 11, the first electrode of the first transistor T1 (located in the second active layer 32) is connected to one end of the third connection line 113 via a first-type via K1, and the first gate G1 of the driving transistor T0 is connected to the other end of the third connection line 113 via a second-type via K2, realizing a connection between the first electrode of the first transistor T1 and the first gate G1 of the driving transistor T0. The second-type via K2 is a via that extends through the interlayer insulating layer 140, the second gate insulating layer 130, the first gate insulating layer 120 and the capacitor insulating layer 110. As shown in FIG. 12, the second electrode of the first transistor T1 (located in the second active layer 32) is connected to one end of the fourth connection line 114 via the first-type via K1, and the second electrode of the driving transistor T0 (located in the first active layer 31) is connected to the other end of the fourth connection line 114 via the first-type via K1, realizing a connection between the second electrode of the first transistor T1 and the second electrode of the driving transistor T0. In this embodiment, a bridge-crossing connection between the first transistor T1 and the driving transistor T0 is realized by means of the third connection line 113 and the fourth connection line 114 located in the fourth conductive layer, which helps to optimize the layout of the lines while reducing parasitic capacitance in the lines.

Further, referring to FIG. 7, the pixel circuit further includes a second transistor T2 connected to the second node N2. The second node N2 is also connected to a light-emitting diode D1, and the second transistor T2 is used for initializing a first electrode (anode) of the light-emitting diode D1.

Specifically, in conjunction with FIG. 9 and FIG. 10, the active layer 30 further includes a third active layer 33. The third active layer 33 extends in the second direction Y. The first active layer 31, the second active layer 32 and the third active layer 33 are in the same layer but are not connected to each other, and a channel region of the second transistor T2 is located in the third active layer 33. In one embodiment, the second active layer 32 and the third active layer 33 are located on the same side of the first active layer 31 to optimize the layout.

The channel region of the second transistor T2 is located at an orthographic projection of a gate of the second transistor T1 on the third active layer 33, and a gate of the second transistor T2 is located in the third conductive layer. For example, the second metal line 52 located in the third conductive layer serves as the gate of the second transistor T2.

FIG. 13 is a schematic diagram of a cross-sectional structure of another display panel according to an embodiment of the present application, where FIG. 13 specifically shows a cross-sectional structure of the display panel shown in FIG. 10 taken along a sectional line FF′. In conjunction with FIG. 10 and FIG. 13; the fourth conductive layer further includes a fifth connection line 115, the display panel further includes a first initialization signal line VRE1, a first electrode of the second transistor T2 is connected to the first initialization signal line VRE1 via the first-type via K1, and a second electrode of the second transistor T2 is connected to the first plate 11 of the first capacitor C1 via the fifth connection line 115.

Specifically, the second electrode of the second transistor T2 is connected to one end of the fifth connection line 115 via the first-type via K1, and the first plate 11 of the first capacitor C1 is connected to the other end of the fifth connection line 115 via the second-type via K2, realizing a connection between the second transistor T2 and the first capacitor C1.

In one embodiment, an orthographic projection of the third active layer 33 on the substrate 10 overlaps an orthographic projection of the first initialization signal line VRE1 on the substrate 10. At an intersection (i.e., where the projections of the two overlap) of the first initialization signal line VRE1 and the third active layer 33, the first initialization signal line VRE1 is connected to the first electrode of the second transistor T2 via the first-type via K1, without the need for connection by a crossover line. The first initialization signal line VRE1 is located in the fourth conductive layer and extends in the first direction X.

Further referring to FIG. 10, the display panel also includes a first scan signal line S1 located in the fourth conductive layer. In this embodiment, since the gates of the first transistor T1 and the second transistor T2 are both connected to the first scan signal line S1, and the gates of the first transistor T1 and the second transistor T2 are both the second metal line 52, that is, the gates of the two transistors are connected into an integrated structure, the first scan signal line S1 may be connected to the gate of the first transistor T1 and/or the gate of the second transistor T2.

In one embodiment, the first scan signal line S1 may be connected to either of the gates of the first transistor T1 and the second transistor T2 to reduce the number of openings, which helps to improve the signal transmission quality. For example, as shown in FIG. 10, the first scan signal line S1 is connected to the gate of the second transistor T2 via the first-type via K1. In one embodiment, the first scan signal line S1 intersects the gate of the second transistor T2, and at an intersection of the first scan signal line S1 and the gate of the second transistor T2, the gate of the second transistor T2 is connected to the first scan signal line S1 via the first-type via K1.

Of course, in other embodiments, the first scan signal line S1 may also be connected to the gate of the first transistor T1 via the first-type via. For example, the first scan signal line S1 intersects each of the gate of the first transistor T1 and the gate of the second transistor T2. At an intersection of the first scan signal line S1 and the gate of the first transistor T1, the first scan signal line S1 is connected to the gate of the first transistor T1 via the first-type via K1.

In one embodiment, further referring to FIG. 11 and FIG. 13, the first conductive layer further includes a first light-shielding layer 12, the first light-shielding layer 12 is in the same layer as but is not connected to the first plate 11 of the first capacitor C1. An orthographic projection of the first light-shielding layer 12 on the substrate 10 at least partially covers an orthographic projection of the channel region of the first transistor T1 and an orthographic projection of the channel region of the second transistor T2 on the substrate 10 to provide bottom light-shielding for the first transistor T1 and the second transistor T2, to avoid variations in the electrical performance of the first transistor T1 and the second transistor T2 caused by light irradiation, which helps to improve the reliability of the pixel circuit and thus improves the reliability of the screen.

Further referring to FIG. 7, the pixel circuit provided in this embodiment further includes a second capacitor C2, a third transistor T3 and a fourth transistor T4, and the display panel further includes a second initialization signal line VRE2 and a data line data. A first electrode of the third transistor T3 is connected to the second initialization signal line VRE2, a second electrode of the third transistor T3 and a second electrode of the fourth transistor T4 are connected to a third node N3, and a first electrode of the fourth transistor T4 is connected to the data line data. The second capacitor C2 is connected between the first node N1 and the third node N3. The third transistor T3 is used for transmitting a fixed voltage to the third node N3, the fourth transistor T4 is used for transmitting a data voltage to the third node N3, and the second capacitor C2 is used for coupling a voltage variation of the third node N3 to the first node N1, and transmitting via the first transistor T1 to the first gate G1 of the driving transistor T0, and the voltage of the first gate G1 of the driving transistor T0 is associated with the data voltage.

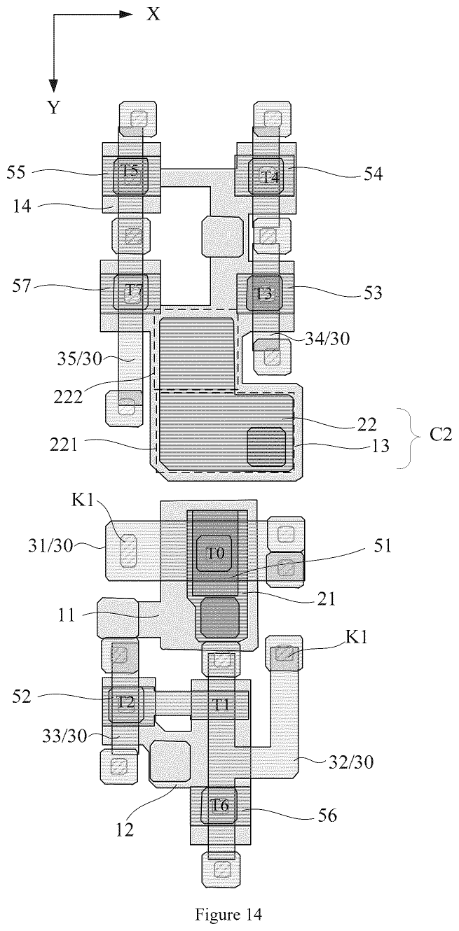

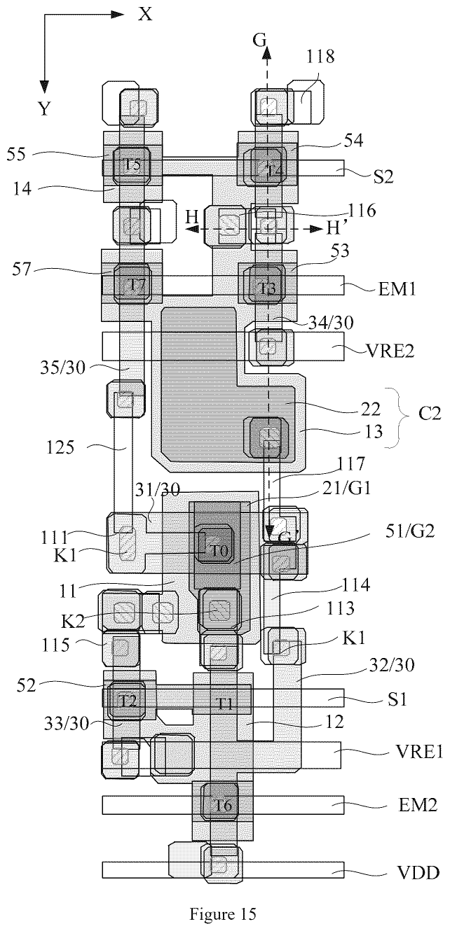

FIG. 14 is a schematic diagram of a planar structure of another display panel according to an embodiment of the present application, and FIG. 15 is a schematic diagram of a planar structure of another display panel according to an embodiment of the present application. Referring to FIG. 14 and FIG. 15, on the basis of the above embodiments, in one embodiment, the active layer 30 further includes a fourth active layer 34. The fourth active layer 34 extends in the second direction. The fourth active layer 34, the third active layer 33, the second active layer 32 and the first active layer 31 are in the same layer but are not connected to each other, and a channel region of the third transistor T3 is located in the fourth active layer 34.

Specifically, the channel region of the third transistor T3 is located at an orthographic projection of a gate of the third transistor T3 on the fourth active layer 34, and the first electrode of the third transistor T3 is connected to the second initialization signal line VRE2 via the first-type via K1. For example, an orthographic projection of the fourth active layer 34 on the substrate 10 overlaps an orthographic projection of the second initialization signal line VRE2 on the substrate 10, and at an intersection of the fourth active layer 34 and the second initialization signal line VRE2, the first electrode of the third transistor T3 is connected to the second initialization signal line VRE2 via the first-type via K1, without the need for connection by a crossover line.

The fourth conductive layer further includes a sixth connection line 116 and a seventh connection line 117. The second electrode of the third transistor T3 is connected to a first plate 13 of the second capacitor C2 via the sixth connection line 116, and a second plate 22 of the second capacitor C2 is connected to the second electrode of the driving transistor T0 via the seventh connection line 117. The first plate 13 of the second capacitor C2 is located in the first conductive layer, and the second plate 22 of the second capacitor C2 is located in the second conductive layer.

In one embodiment, the display panel further includes a first light-emission control signal line EM1, the first light-emission control signal line EM1 is located in the fourth conductive layer, and the first light-emission control signal line EM1 is connected to the gate of the third transistor T3 via the first-type via K1. A fourth metal line 54 located in the third conductive layer serves as the gate of the third transistor T3.

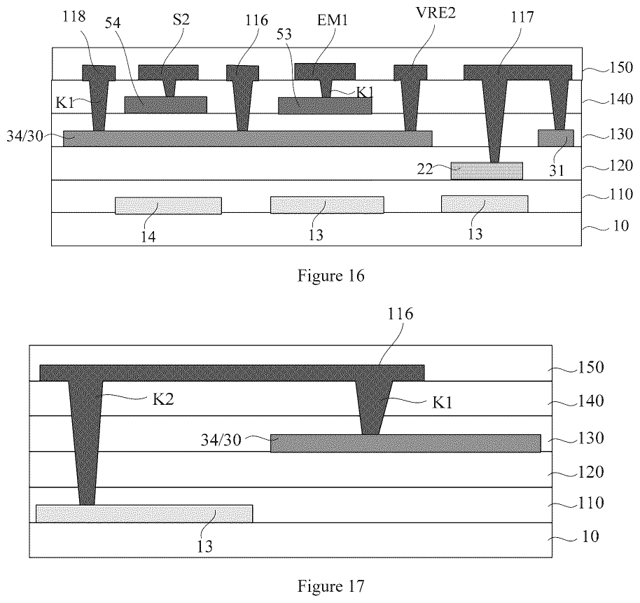

FIG. 16 is a schematic diagram of a cross-sectional structure of another display panel according to an embodiment of the present application, and specifically, a cross-sectional structure of the display panel shown in FIG. 15 taken along a sectional line GG′, and FIG. 17 is a schematic diagram of a cross-sectional structure of another display panel according to an embodiment of the present application, specifically, a cross-sectional structure of the display panel shown in FIG. 15 taken along a sectional line HH′. In conjunction with FIG. 15, FIG. 16 and FIG. 17, the second electrode of the third transistor T3 is connected to one end of the sixth connection line 116 via the first-type via K1, the first plate 13 of the second capacitor C2 is connected to the other end of the sixth connection line 116 via the second-type via K2, the second plate 22 of the second capacitor C2 is connected to one end of the seventh connection line 117 via the second-type via K2, and the second electrode of the driving transistor T0 is connected to the other end of the seventh connection line 117 via the first-type via K1.

Specifically, the orthographic projection of the fourth active layer 34 on the substrate 10 overlaps the orthographic projection of the second initialization signal line VRE2 on the substrate 10, and at the intersection of the fourth active layer 34 and the second initialization signal line VRE2, the first electrode of the third transistor T3 is connected to the second initialization signal line VRE2 via the first-type via K1. The first light-emission control signal line EM1 intersects the gate of the third transistor T3, and at an intersection of the first light-emission control signal line EM1 and the gate of the third transistor T3, the first light-emission control signal line EM1 is connected to the gate of the third transistor T3 via the first-type via K1.

In one embodiment, the first light-emission control signal line EM1 and the second initialization signal line VRE2 both extend in the first direction X and are both located in the fourth conductive layer, and the first light-emission control signal line EM1 is located on a side of the second initialization signal line VRE2 away from the first active layer 31, to facilitate wiring, thereby increasing layout space utilization.

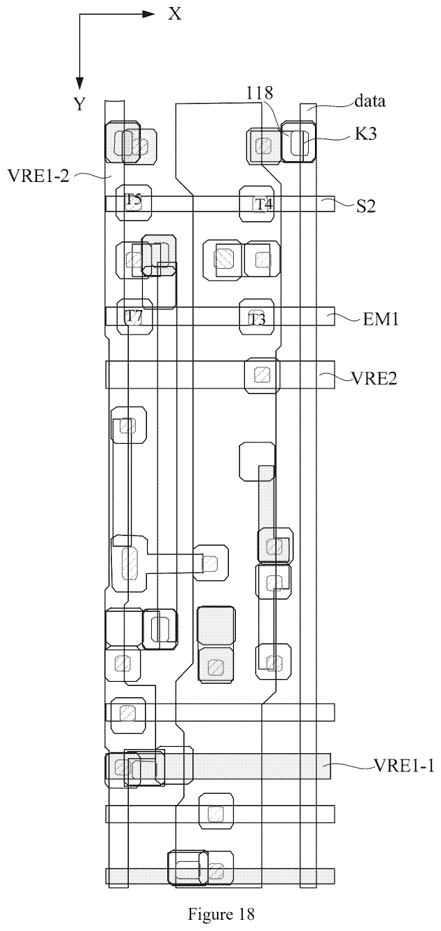

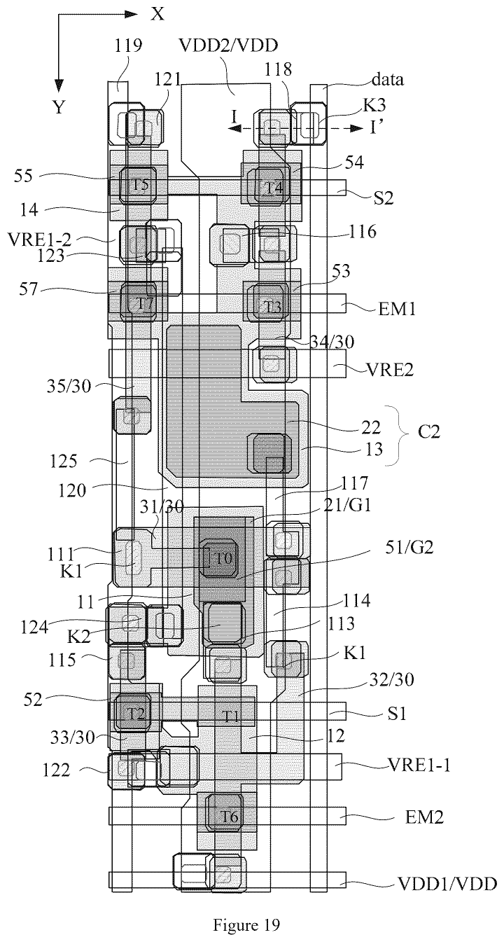

FIG. 18 is a schematic diagram of a planar structure of another display panel according to an embodiment of the present application, and FIG. 19 is a schematic diagram of a planar structure of another display panel according to an embodiment of the present application, where FIG. 18 shows only the structures of the fourth conductive layer and a fifth conductive layer. Referring to FIGS. 15 to 19, a channel region of the fourth transistor T4 is located at an orthographic projection of a gate of the fourth transistor T4 on the fourth active layer 34, and the gate of the fourth transistor T4 is located in the third conductive layer. For example, the fourth metal line 54 located in the third conductive layer serves as the gate of the fourth transistor T4.

In this embodiment, the fourth transistor T4 further includes an eighth connection line 118. The first electrode of the fourth transistor T4 is connected to the data line data via the eighth connection line 118, and the second electrode of the fourth transistor T4 is connected to the second electrode of the third transistor T3 via the fourth active layer 34. The display panel further includes a second scan signal line S2, the second scan signal line S2 is located in the fourth conductive layer, and the second scan signal line S2 is connected to the gate of the fourth transistor T4 via the first-type via K1, that is, the second scan signal line S2 is connected to the fourth metal line 54 via the first-type via K1. The second scan signal line S2 extends in the first direction X.

Specifically, further referring to FIG. 16, the first electrode and the second electrode of the fourth transistor T4 are both located in the fourth active layer 34 and on two sides of the channel region of the fourth transistor T4, respectively. The first electrode of the fourth transistor T4 is connected to one end of the eighth connection line 118 via the first-type via K1. Since the fourth transistor T4 and the third transistor T3 share the fourth active layer 34, the second electrode of the fourth transistor T4 is directly connected to the second electrode of the third transistor T3 via the fourth active layer 34. The second scan signal line S2 intersects the gate of the fourth transistor T4, and at an intersection of the second scan signal line S2 and the gate of the fourth transistor T4, the second scan signal line S2 is connected to the gate of the fourth transistor T4 via the first-type via K2, without a crossover line, thus helping to reduce the number of vias.

In one embodiment, an orthographic projection of the first light-emission control signal line EM1 on the substrate 10 is located between the orthographic projection of the second initialization signal line VRE2 on the substrate 10 and an orthographic projection of the second scan signal line S2 on the substrate 10; and in the second direction Y, the first light-emission control signal line EM1, the second scan signal line S2 and the second initialization signal line VRE2 are located on the same side of the first active layer 31, and the first initialization signal line VRE1 and the first scan signal line S1 are located on the other side of the first active layer 31. The purpose of this arrangement is to optimize the positions of the transistors in the layout to reduce the layout space occupied, thereby increasing the layout space utilization and increasing the limit PPI of the screen.

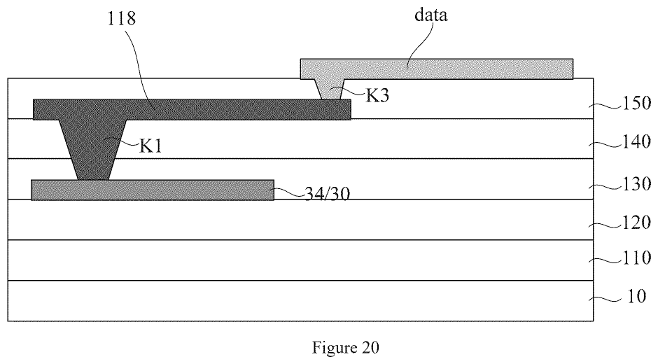

FIG. 20 is a schematic diagram of a cross-sectional structure of another display panel according to an embodiment of the present application, and specifically, a cross-sectional structure of the display panel shown in FIG. 19 taken along a sectional line II′. Referring to FIG. 19 and FIG. 20, since the data line data extends in the second direction Y, the data line data and the second scan signal line S2 are disposed in different layers, to simplify the wiring. For example, the data line data may be located in the fifth conductive layer, the fifth conductive layer is located on a side of the fourth conductive layer away from the substrate 10, and the first planarization layer 150 is disposed between the fifth conductive layer and the fourth conductive layer. The first electrode of the fourth transistor T4 is connected to one end of the eighth connection line 118 via the first-type via K1, and the data line data is connected to the other end of the eighth connection line 118 via a third-type via K3, thus realizing a connection between the fourth transistor and the data line data.

In one embodiment, the first plate 13 of the second capacitor C2 is located in the first conductive layer, the second plate 22 of the second capacitor C2 is located in the second conductive layer, and an overlap between the first plate 13 and the second plate 22 of the second capacitor C2 forms an effective region of the second capacitor C2. In this embodiment, the second plate 22 of the second capacitor C2 is shaped in an L shape due to the presence of the first-type via K1 between the second initialization signal line VRE2 and the fourth active layer 34. An orthographic projection of the second plate 22 of the second capacitor C2 on the substrate 10 at least partially overlaps the orthographic projection of the second initialization signal line VRE2 on the substrate 10, and the capacitance value of the second capacitor C2 meets the requirements.

As an example, in conjunction with FIG. 15, the second plate 22 of the second capacitor C2 includes a main portion 221 extending in the first direction X and a branch portion 222 extending in the second direction Y, an orthographic projection of the branch portion 222 on the substrate 10 overlaps the orthographic projection of the second initialization signal line VRE2 on the substrate 10, and an orthographic projection of the main portion 221 on the substrate 10 is located between the orthographic projection of the second initialization signal line VRE2 on the substrate 10 and an orthographic projection of the first active layer 31 on the substrate 10. The main portion 221 and the branch portion 222 are of an integrated structure.

Further referring to FIG. 15 and FIG. 19, in this embodiment, an orthographic projection of the first plate 13 of the second capacitor C2 on the substrate 10 at least partially covers an orthographic projection of the channel region of the third transistor T3 on the substrate 10. The first conductive layer further includes a second light-shielding layer 14. The second light-shielding layer 14 is in the same layer as, but is not connected to the first light-shielding layer 12 and the first plate 11 of the first capacitor C1. An orthographic projection of the second light-shielding layer 14 on the substrate 10 at least partially covers an orthographic projection of the channel region of the fourth transistor T4 on the substrate 10. In one embodiment, the orthographic projection of the first plate 13 of the second capacitor C2 on the substrate 10 completely covers the orthographic projection of the channel region of the third transistor T3 on the substrate 10, and the orthographic projection of the second light-shielding layer 14 on the substrate 10 completely covers the orthographic projection of the channel region of the fourth transistor T4 on the substrate 10, to realize bottom shielding for the third transistor T3 and the fourth transistor T4, and avoid variations in the electrical performance of the third transistor T3 and the fourth transistor T4 caused by light irradiation, which helps to improve the reliability of the pixel circuit and thus improves the reliability of the screen.

Further referring to FIG. 7, FIG. 16 and FIG. 19, on the basis of the above embodiments, in one embodiment, the pixel circuit provided in this embodiment further includes a fifth transistor T5. A first electrode of the fifth transistor T5 is connected to the second electrode of the second transistor T2, a second electrode of the fifth transistor T5 is connected to the first electrode of the second transistor T2, and the fifth transistor T5 is used for initializing the light-emitting diode D1 during a holding frame, to realize low-frequency driving.

The active layer 30 further includes a fifth active layer 35. The fifth active layer 35 is in the same layer as but is not connected to the fourth active layer 34, the third active layer 33, the second active layer 32 and the first active layer 31, and a channel region of the fifth transistor T5 is located in the fifth active layer 35. The fifth active layer 35 and the fourth active layer 34 are located on the other side of the first active layer 31, and are on a different side of the first active layer 31 from the third active layer 33 and the second active layer 32.

Specifically, the channel region of the fifth transistor T5 is located at an orthographic projection of a gate of the fifth transistor T5 on the fifth active layer 35, and a fifth metal line located in the third conductive layer may serve as the gate of the fifth transistor T5. The second electrode of the fifth transistor T5 is connected to the first electrode of the second transistor via a ninth connection line, the first electrode of the fifth transistor is connected to the second electrode of the second transistor via a tenth connection line, and the gate of the fifth transistor is connected to the second scan signal line via the first-type via. The second scan signal line intersects the gate of the fifth transistor, and at an intersection of the second scan signal line and the gate of the fifth transistor, the gate of the fifth transistor is connected to the second scan signal line via the first-type via.

Specifically, the ninth connection line 119 and the tenth connection line 120 are both located in the fifth conductive layer. The fourth conductive layer further includes an eleventh connection line 121, a twelfth connection line 122, a thirteenth connection line 123 and a fourteenth connection line 124. The second electrode of the fifth transistor T5 is connected to one end of the eleventh connection line 121 via the first-type via K1, the other end of the eleventh connection line 121 is connected to one end of the ninth connection line 119 via the third-type via K3, the other end of the ninth connection line 119 is connected to one end of the twelfth connection line 122 via the third-type via K3, and the other end of the twelfth connection line 122 is connected to the first electrode of the second transistor T2 via the first-type via K1. The first electrode of the fifth transistor T5 is connected to one end of the thirteenth connection line 123 via the first-type via K1, the other end of the thirteenth connection line 123 is connected to one end of the tenth connection line 120 via the third-type via K3, the other end of the tenth connection line 120 is connected to one end of the fourteenth connection line 124 via the third-type via K3, and the other end of the fourteenth connection line 124 is connected to the second electrode of the second transistor T2 via the first-type via K2.

The connection manner between the fifth transistor T5 and the second transistor T2 is the same as the connection manner between the fourth transistor T4 and the data line data, both of which are interconnected via the fourth conductive layer and the fifth conductive layer, and details are not repeated herein.

In one embodiment, the orthographic projection of the second light-shielding layer 14 on the substrate 10 at least partially covers an orthographic projection of the channel region of the fifth transistor T5 on the substrate 10. In one embodiment, the orthographic projection of the second light-shielding layer 14 on the substrate 10 completely covers the orthographic projection of the channel region of the fifth transistor T5 on the substrate 10, to realize bottom shielding for the fifth transistor T5, and avoid variations in the electrical performance of the fifth transistor T5 caused by light irradiation, which helps to improve the reliability of the pixel circuit and thus improves the reliability of the screen.

In one embodiment, since the second electrode of the second transistor T2, the first electrode of the fifth transistor T5 and the first plate 11 of the first capacitor C1 are connected to the second node N2, the fourteenth connection line 124 and the fifth connection line 115 may be the same connection line.

In one embodiment, further referring to FIG. 19, in this embodiment, the first initialization signal line VRE1 includes a first sub-signal line VRE1-1 extending in the first direction X and a second sub-signal line VRE1-2 extending in the second direction Y. The first sub-signal line VRE1-1 and the second sub-signal line VRE1-2 are connected at at least one intersection to form a mesh structure. The first sub-signal line VRE1-1 and the second sub-signal line VRE1-2 are disposed in different layers. For example, the first sub-signal line VRE1-1 is located in the fourth conductive layer, and the second sub-signal line VRE1-2 is located in the fifth conductive layer. Since the fifth transistor T5 and the second transistor T2 are both connected to the first initialization signal line VRE1, the second sub-signal line VRE1-2 may be multiplexed as the ninth connection line 119 at a position where the first electrode of the fifth transistor T5 is connected to the second electrode of the second transistor T2, which helps to reduce the number of connection lines to increase PPI.

In one embodiment, an orthographic projection of the first sub-signal line VRE1-1 on the substrate 10 is located on a side of an orthographic projection of the first scan signal line S1 on the substrate 10 away from an orthographic projection of the first gate G1 of the driving transistor T0 on the substrate 10.

An orthographic projection of the second sub-signal line VRE1-2 on the substrate 10 covers orthographic projections of the channel regions of part of the transistors on the substrate 10 to provide top shielding for the part of the transistors. For example, the orthographic projection of the second sub-signal line VRE1-2 on the substrate 10 covers at least the orthographic projection of the channel region of the second transistor T2 on the substrate 10. In combination with bottom shielding for the channel region of the second transistor T2 by the first light-shielding layer 12, the impact of light irradiation on the second transistor T2 can be avoided.

In this embodiment, the orthographic projection of the first scan signal line S1 on the substrate 10 is located between the orthographic projection of the first active layer 31 on the substrate 10 and the orthographic projection of the first sub-signal line VRE1-1 (the first initialization signal line VRE1 extending in the first direction X) on the substrate 10, and the first scan signal line S1 is disposed close to the first gate G1 of the driving transistor T0, which can reduce crossover lines connected to the first sub-signal line VRE1-1, reducing parasitic capacitance at the first gate G1 and the second gate G2 of the driving transistor T0, helping to reduce display crosstalk, and thus improving luminance uniformity.

Further referring to FIG. 19, the pixel circuit provided in this embodiment further includes a sixth transistor T6 and a seventh transistor T7, and the display panel further includes a power line VDD. A first electrode of the sixth transistor is connected to the second electrode of the driving transistor T0, a second electrode of the sixth transistor T0 is connected to the power line VDD, a first electrode of the seventh transistor T7 is connected to the second node N2, and a second electrode of the seventh transistor T7 is connected to the first electrode of the driving transistor T0. The sixth transistor T6 and the seventh transistor T7 are used for controlling the transmission of a power voltage on the power line VDD to the light-emitting diode D1.

Specifically, in conjunction with FIG. 16 and FIG. 19, the fourth conductive layer further includes a fifteenth connection line 125. The second electrode of the sixth transistor T6 is connected to the power line VDD via the first-type via K1, and the first electrode of the sixth transistor T6 is connected to the second electrode of the driving transistor T0 via the fourth connection line 114; and the second electrode of the seventh transistor T7 is connected to the first electrode of the driving transistor T0 via the fifteenth connection line 125, and the first electrode of the seventh transistor T7 is connected to the thirteenth connection line 123.

As an example, the first electrode of the sixth transistor T6 is connected to one end of the fourth connection line 114 via the first-type via K1, and the second electrode of the driving transistor T0 is connected to the other end of the fourth connection line 114 via the first-type via K1; and the second electrode of the seventh transistor T7 is connected to one end of the fifteenth connection line 125 via the first-type via K1, the first electrode of the driving transistor T0 is connected to the other end of the fifteenth connection line 125 via the first-type via K1, and the first electrode of the seventh transistor T7 is connected to the thirteenth connection line 123 via the first-type via K1.

In one embodiment, the power line VDD includes a third sub-signal line VDD1 extending in the first direction X and a fourth sub-signal line VDD2 extending in the second direction Y. The third sub-signal line VDD1 and the fourth sub-signal line VDD2 are located in different conductive layers, and the third sub-signal line VDD1 and the fourth sub-signal line VDD2 are connected at at least one intersection to form a mesh structure. For example, at the intersection of the third sub-signal line VDD1 and the fourth sub-signal line VDD2, the third sub-signal line VDD1 and the fourth sub-signal line VDD2 are connected via the third-type via K3 to form a mesh structure. The third sub-signal line VDD1 may be located in the fourth conductive layer, and the fourth sub-signal line VDD2 may be located in the fifth conductive layer.

The third sub-signal line VDD1 included in the power line VDD intersects the second active layer 32. At an intersection of the third sub-signal line VDD1 and the second active layer 32, the second electrode of the sixth transistor T6 is connected to the third sub-signal line VDD1 via the first-type via K1, which helps to reduce the number of crossover lines in the layout and lower the parasitic capacitance of the sixth transistor T6.

The display panel further includes a second light-emission control signal line extending in the first direction. The orthographic projection of the first light-emission control signal line on the substrate and an orthographic projection of the second light-emission control signal line on the substrate are respectively located on two sides of the orthographic projection of the first active layer on the substrate. The orthographic projection of the second light-emission control signal line on the substrate is located on a side of the orthographic projection of the first initialization signal line on the substrate away from the orthographic projection of the first scan signal line on the substrate.

A gate of the sixth transistor T6 is connected to the second light-emission control signal line EM2 via the first-type via K1, and a gate of the seventh transistor T7 is connected to the first light-emission control signal line EM1 via the first-type via K1. As an example, the second light-emission control signal line EM2 intersects the gate of the sixth transistor T6, and at an intersection of the second light-emission control signal line EM2 and the gate of the sixth transistor T6, the gate of the sixth transistor T6 is connected to the second light-emission control signal line EM2 via the first-type via K1; and the first light-emission control signal line EM1 intersects the gate of the seventh transistor T7, and at an intersection of the first light-emission control signal line EM1 and the gate of the seventh transistor T7, the gate of the seventh transistor T7 is connected to the first light-emission control signal line EM1 via the first-type via K1. Here, the connection manner between the first light-emission control signal line EM and the gate of the seventh transistor T7 is the same as the connection manner between the first light-emission control signal line EM and the gate of the third transistor T3, with the same cross-sectional structure. Specific reference may be made to the relevant description in FIG. 17. Similarly, the connection manner between the second light-emission control signal line EM2 and the gate of the sixth transistor T6 is the same as the connection manner between the first light-emission control signal line EM and the gate of the third transistor T3, which will not be described in detail.

In one embodiment, an orthographic projection of the third sub-signal line VDD1 on the substrate 10 is located on a side of the orthographic projection of the second light-emission control signal line EM2 on the substrate 10 away from the orthographic projection of the first initialization signal line VRE1 on the substrate 10, and specifically on a side of the orthographic projection of the second light-emission control signal line EM2 on the substrate 10 away from the orthographic projection of the first sub-signal line VRE1-1 on the substrate 10.

In this embodiment, the orthographic projection of the first light-shielding layer 12 on the substrate 10 at least partially covers an orthographic projection of the channel region of the sixth transistor T6 on the substrate 10; and the orthographic projection of the first plate 13 of the second capacitor C2 on the substrate 10 at least partially covers an orthographic projection of the channel region of the seventh transistor T7 on the substrate 10. Moreover, an orthographic projection of the fourth sub-signal line VDD2 on the substrate 10 covers orthographic projections of the channel regions of part of the transistors on the substrate 10. For example, the orthographic projection of the fourth sub-signal line VDD2 on the substrate 10 covers the orthographic projections of the channel region of the first transistor T1, the channel region of the third transistor T3, the channel region of the fourth transistor T4, the channel region of the driving transistor T0 and the channel region of the sixth transistor T6 on the substrate 10.

In one embodiment, since the fourth active layer 34 corresponding to the third transistor T3 and the fourth transistor T4, and the fifth active layer 35 corresponding to the fifth transistor T5 and the seventh transistor T7 are both located on the same side of the first active layer 31, the second light-shielding layer 14 and the first plate 13 of the second capacitor C2 may be connected as an integrated structure in the first conductive layer, and together provide bottom light-shielding for the transistors on the same side of the first active layer 31, which helps to save the area of the layout.

According to this embodiment, bottoms of the transistors are shielded by the first conductive layer, and tops of the transistors are shielded by the fifth conductive layer, which can avoid the impact of light irradiation on the transistors, thereby improving the reliability of the pixel circuit and thus improving the stability of the screen.

In the above embodiments, the first scan signal line S1 intersects the gate of the first transistor T1 and the gate of the second transistor T2, the second scan signal line S2 intersects the gate of the fourth transistor T4 and the gate of the fifth transistor T5, the first light-emission control signal line EM1 intersects the gates of the third transistor T3 and the seventh transistor T7, and the second light-emission control signal line EM2 intersects the gate of the sixth transistor T6, which can reduce the number of crossover lines. In addition, since each signal line is used for inputting a voltage signal, the signal lines can also serve to shield signals for the gates of the respective transistors covered thereby, thereby ensuring the stability of the gate voltages of the transistors and helping to improve the display luminance uniformity.

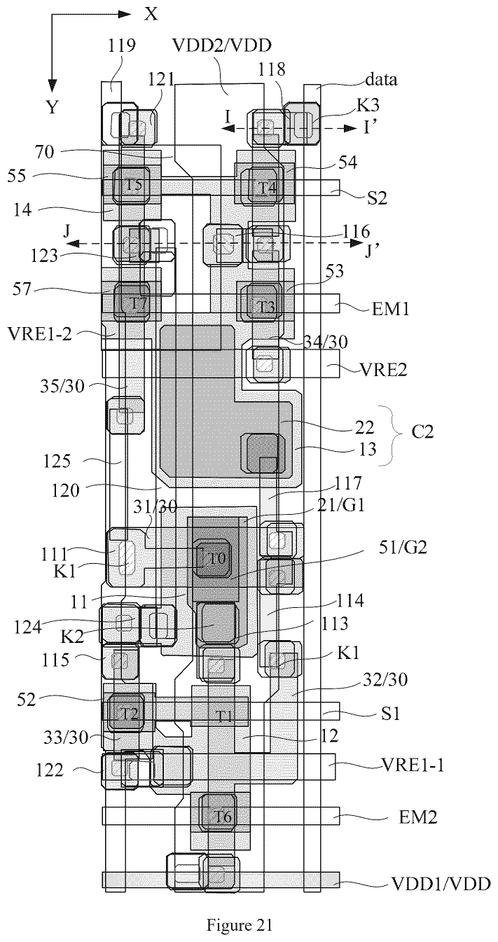

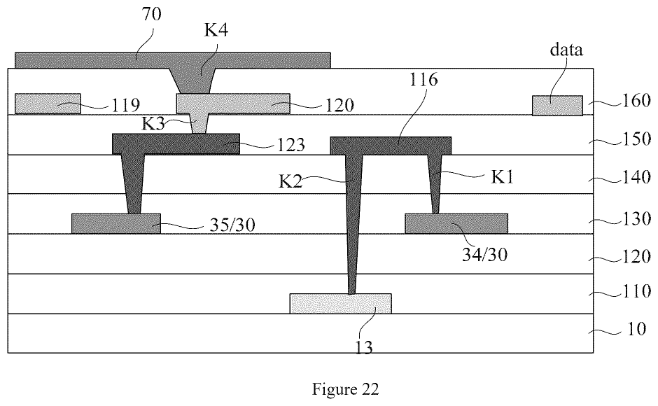

FIG. 21 is a schematic diagram of a planar structure of another display panel according to an embodiment of the present application, and FIG. 22 is a schematic diagram of a cross-sectional structure of another display panel according to an embodiment of the present application, and specifically, a cross-sectional structure of the display panel shown in FIG. 21 taken along a sectional line JJ′. Referring to FIG. 21 and FIG. 22, on the basis of the above embodiments, in one embodiment, the display panel further includes light-emitting elements, which may be the light-emitting diode D1. Each light-emitting element includes a first electrode 70, a light-emitting functional layer and a second electrode (not shown) that are stacked. The first electrode 70 is located on a side of the fifth conductive layer away from the substrate 10, and a second planarization layer 160 is provided between the fifth conductive layer and the first electrode 70.

The first electrode 70 is connected to one end of the tenth connection line 120 via a fourth-type via K4 to realize a connection between the light-emitting element and the first electrode of the seventh transistor T7. The fourth-type via K4 is a via that extends through the second planarization layer 160.

In this embodiment, an orthographic projection of the first electrode 70 on the substrate 10 covers at least the orthographic projections of the channel regions of the remaining transistors on the substrate 10. Here, the remaining transistors refer to transistors that are not shielded by the fifth conductive layer, such as the fifth transistor T5 and the seventh transistor T7. The tops of the remaining transistors are shielded by the first electrode 70, thereby enabling film layers with a light-shielding function to be provided at the tops and bottoms of all the transistors, to improve the stability of the screen.

According to the embodiments of the present application, the first conductive layer serves as the first plate 11 of the first capacitor C1 and a light-shielding layer for the bottoms of the transistors; the first conductive layer serves as the second plate 21 of the first capacitor C1 and the first gate G1 of the driving transistor T0; the fifth conductive layer serves as the fourth sub-signal line VDD2 of the power line VDD and also serves to shield the tops of part of the transistors; the first electrode 70 serves as an electrode of the light-emitting element and serves to shield the tops of the remaining transistors, which can avoid the impact of light irradiation on the transistors while fully increasing the layout space utilization, helping to improve the stability and reliability of the screen. In addition, according to this embodiment, the first scan signal line S1 is disposed close to the driving transistor T0, which can effectively reduce the connection crossover lines of the first scan signal line S1, thereby reducing the parasitic capacitance of the gate of the driving transistor T0. Moreover, the gates of the transistors (all being top gates) are shielded by the fourth metal layer, which helps to reduce the parasitic capacitance of the gates of the transistors, helping to reduce display crosstalk, and thus improving display uniformity.

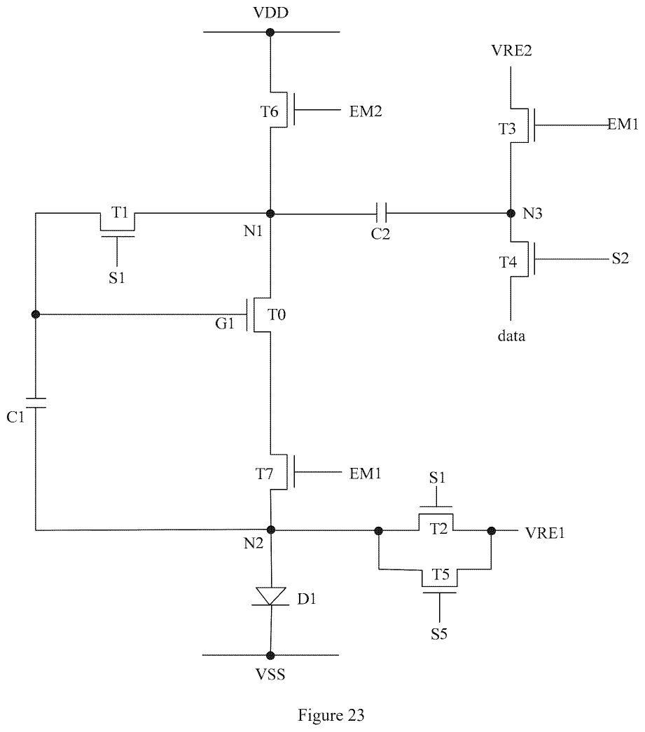

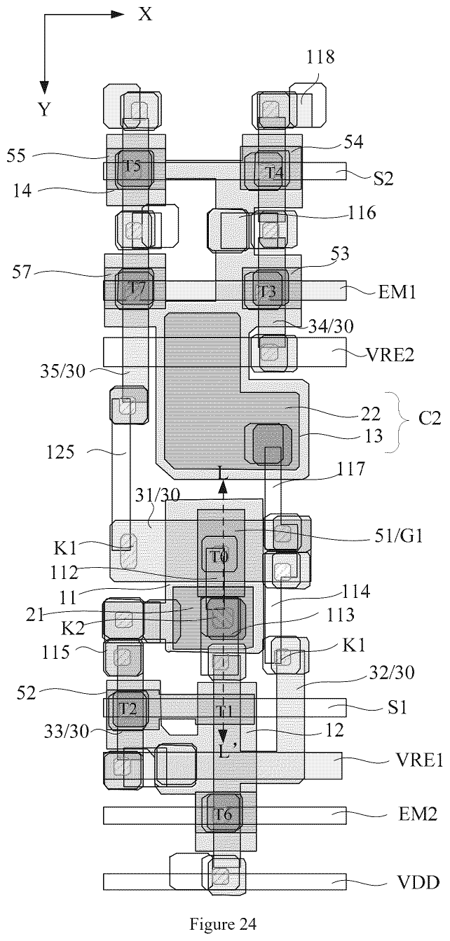

FIG. 23 is a schematic structural diagram of another pixel circuit according to an embodiment of the present application, and FIG. 24 is a schematic diagram of a planar structure of another display panel according to an embodiment of the present application. Referring to FIG. 23 and FIG. 24, in this embodiment, the driving transistor T0 is a single-gate transistor. That is, the driving transistor T0 has only a first gate G1 and the second plate 21 of the first capacitor C1 no longer serves as a gate of the driving transistor T0. Therefore, the orthographic projection of the second plate 21 of the first capacitor C1 on the substrate 10 does not overlap the orthographic projection of the channel region of the driving transistor T0 on the substrate 10. The first gate G1 of the driving transistor T0 is located in the third conductive layer. Compared with the layout of the driving transistor T0 shown in FIG. 16 being a dual-gate transistor, when the driving transistor T0 is a single-gate transistor, the first connection line 111 can be omitted, and the connection between the first gate G1 of the driving transistor T0 and the second plate 21 of the first capacitor C1 is realized via the second connection line 112.

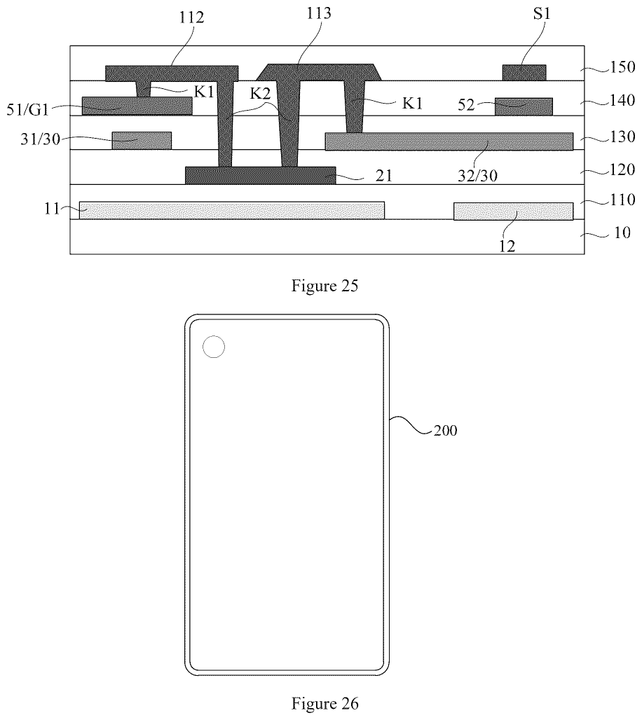

FIG. 25 is a schematic diagram of a cross-sectional structure of another display panel according to an embodiment of the present application, and specifically, a cross-sectional structure of the display panel shown in FIG. 24 taken along a sectional line LL′. As shown in FIG. 25, the first gate G1 of the driving transistor T0 is connected to one end of the second connection line 112 via the first-type via K1, and the second plate 21 of the first capacitor C1 is connected to the other end of the second connection line 112 via the second-type via K2.

In one embodiment, the second connection line 112 may be connected to the third connection line 113 as an integrated structure to reduce one second-type via K2.

When the driving transistor T0 is a single-gate transistor, the layout structures of the other transistors are the same as or similar to the layout structures of the corresponding transistors when the driving transistor T0 is a dual-gate transistor, specifically as shown in FIGS. 16 to 21. These transistors also possess the same advantageous effects as those described in any of the above embodiments, which will not be described in detail herein.

In one embodiment, for the specific working principle of the pixel circuit provided in the above embodiments, reference may be made to the description in the related art, which will not be repeated herein.

In one embodiment, the embodiments of the present application further provide a display device, including a display panel according to any of the embodiments of the present application. Therefore, the display device also has the advantageous effects described in any of the above embodiments. FIG. 26 is a schematic structural diagram of a display device according to an embodiment of the present application. In this embodiment, the display device 200 may be a mobile phone or any electronic product having a display function, including but not limited to, display panels in products such as a television, a notebook computer, a desktop display, a tablet computer, a digital camera, a smart bracelet, smart glasses, a vehicle-mounted monitor, a medical apparatus, an industrial control apparatus, a touch interactive terminal, etc., which will not be specially limited in the embodiments of the present application.

The steps may be reordered, added, or deleted using the various forms of processes illustrated above. For example, the steps recorded in the present application may be performed in parallel, sequentially, or in a different order, provided that desired results of the embodiments of the present application can be achieved, which are not limited herein.

The above detailed description does not constitute a limitation on the scope of protection of the present application. Various modifications, combinations, sub-combinations, and substitutions can be made based on design requirements and other factors. Any modifications, equivalent substitutions, or improvements made within the spirit and principle of the present application should be included within the scope of protection of the present application.

1. A display panel, comprising:
a substrate;
a plurality of conductive layers stacked on a side of the substrate;
at least one pixel circuit comprising a driving transistor and a first capacitor;
wherein the plurality of conductive layers comprise a first conductive layer and a second conductive layer, the second conductive layer is located on a side of the first conductive layer away from the substrate, a first plate of the first capacitor is located in the first conductive layer, a second plate of the first capacitor is located in the second conductive layer, and the second plate of the first capacitor is connected to a first gate of the driving transistor; and
an active layer located on a side of the second conductive layer away from the substrate.

2. The display panel according to claim 1, wherein the first gate of the driving transistor is located in the second conductive layer, and the second plate of the first capacitor is multiplexed as the first gate of the driving transistor;
the active layer comprises a first active layer extending in a first direction, a channel region of the driving transistor is located in the first active layer, and an orthographic projection of the second plate of the first capacitor on the substrate at least partially covers an orthographic projection of the channel region of the driving transistor on the substrate;
an orthographic projection of the first plate of the first capacitor on the substrate at least partially covers the orthographic projection of the channel region of the driving transistor on the substrate; and
the orthographic projection of the first plate of the first capacitor on the substrate at least partially overlaps the orthographic projection of the second plate of the first capacitor on the substrate.

3. The display panel according to claim 2, wherein the first plate of the first capacitor comprises an aperture region, an overlap between the orthographic projection of the first plate of the first capacitor on the substrate and the orthographic projection of the second plate of the first capacitor on the substrate at least partially covers an orthographic projection of the aperture region on the substrate.

4. The display panel according to claim 2, wherein the plurality of conductive layers further comprise a third conductive layer, the third conductive layer is located on a side of the active layer away from the substrate, a second gate of the driving transistor is located in the third conductive layer, and the second gate of the driving transistor is connected to a first electrode of the driving transistor;
the plurality of conductive layers further comprise a fourth conductive layer, the fourth conductive layer is located on a side of the third conductive layer away from the substrate, the fourth conductive layer comprises a first connection line, and the second gate of the driving transistor is connected to the first electrode of the driving transistor via the first connection line;
the second gate of the driving transistor is connected to one end of the first connection line via a first-type via, and the first electrode of the driving transistor is connected to the other end of the first connection line via the first-type via;
an orthographic projection of the first connection line on the substrate at least partially covers an orthographic projection of the second gate of the driving transistor on the substrate; and
the orthographic projection of the second gate of the driving transistor on the substrate at least partially covers the orthographic projection of the channel region of the driving transistor on the substrate.

5. The display panel according to claim 1, wherein the plurality of conductive layers further comprise a third conductive layer, the third conductive layer is located on a side of the active layer away from the substrate, and the first gate of the driving transistor is located in the third conductive layer;
the active layer comprises a first active layer extending in a first direction, a channel region of the driving transistor is located in the first active layer, an orthographic projection of the first gate of the driving transistor on the substrate at least partially covers an orthographic projection of the channel region of the driving transistor on the substrate; and
an orthographic projection of the second plate of the first capacitor on the substrate does not overlap the orthographic projection of the channel region of the driving transistor on the substrate.

6. The display panel according to claim 5, wherein the plurality of conductive layers further comprise a fourth conductive layer, the fourth conductive layer is located on a side of the third conductive layer away from the substrate, the fourth conductive layer comprises a second connection line, and the first gate of the driving transistor is connected to the second plate of the first capacitor via the second connection line;
the first gate of the driving transistor is connected to one end of the second connection line via a first-type via, and the second plate of the first capacitor is connected to the other end of the second connection line via a second-type via;
the orthographic projection of the second plate of the first capacitor on the substrate does not overlap the orthographic projection of the channel region of the driving transistor on the substrate;
an orthographic projection of the first plate of the first capacitor on the substrate at least partially covers the orthographic projection of the channel region of the driving transistor on the substrate; and
the orthographic projection of the first plate of the first capacitor on the substrate at least partially overlaps the orthographic projection of the second plate of the first capacitor on the substrate.

7. The display panel according to claim 4, wherein the pixel circuit further comprises a first transistor, a gate of the first transistor is located in the third conductive layer, the active layer further comprises a second active layer extending in a second direction intersecting the first direction, the second active layer is in the same layer as but is not connected to the first active layer, and a channel region of the first transistor is located in the second active layer;
the first direction perpendicularly intersects the second direction;
the channel region of the first transistor is located at an orthographic projection of the gate of the first transistor on the second active layer, the fourth conductive layer further comprises a third connection line and a fourth connection line, a first electrode of the first transistor is connected to the first gate of the driving transistor via the third connection line, and a second electrode of the first transistor is connected to a second electrode of the driving transistor via the fourth connection line;
the first electrode of the first transistor is connected to one end of the third connection line via the first-type via, and the first gate of the driving transistor is connected to the other end of the third connection line via the first-type via or a second-type via; and the second electrode of the first transistor is connected to one end of the fourth connection line via the first-type via, and the second electrode of the driving transistor is connected to the other end of the fourth connection line via the first-type via;
the display panel further comprises a first scan signal line, the first scan signal line is located in the fourth conductive layer, and the first scan signal line is connected to the gate of the first transistor via the first-type via;
the first scan signal line intersects the gate of the first transistor, and at an intersection of the first scan signal line and the gate of the first transistor, the first scan signal line is connected to the gate of the first transistor via the first-type via;
the first scan signal line extends in the first direction; and
the first conductive layer further comprises a first light-shielding layer, the first light-shielding layer is in the same layer as but is not connected to the first plate of the first capacitor, and an orthographic projection of the first light-shielding layer on the substrate at least partially covers an orthographic projection of the channel region of the first transistor on the substrate.

8. The display panel according to claim 7, wherein the display panel further comprises a first initialization signal line, the pixel circuit further comprises a second transistor, a gate of the second transistor is located in the third conductive layer, the active layer further comprises a third active layer extending in the second direction, the third active layer, the second active layer and the first active layer are in the same layer but are not connected to each other, and a channel region of the second transistor is located in the third active layer;
the second active layer and the third active layer are located on one side of the first active layer;
the channel region of the second transistor is located at an orthographic projection of the gate of the second transistor on the third active layer, a first electrode of the second transistor is connected to the first initialization signal line via the first-type via, the fourth conductive layer further comprises a fifth connection line, a second electrode of the second transistor is connected to the first plate of the first capacitor via the fifth connection line, and the gate of the second transistor is connected to the first scan signal line via the first-type via;
the second electrode of the second transistor is connected to one end of the fifth connection line via the first-type via, and the first plate of the first capacitor is connected to the other end of the fifth connection line via the second-type via;
an orthographic projection of the third active layer on the substrate overlaps an orthographic projection of the first initialization signal line on the substrate;
at an intersection of the first initialization signal line and the third active layer, the first initialization signal line is connected to the first electrode of the second transistor via the first-type via;
the first scan signal line intersects the gate of the second transistor, and at an intersection of the first scan signal line and the gate of the second transistor, the gate of the second transistor is connected to the first scan signal line via the first-type via;
the first initialization signal line is located in the fourth conductive layer, and the first initialization signal line extends in the first direction; and
the orthographic projection of the first light-shielding layer on the substrate at least partially covers an orthographic projection of the channel region of the second transistor on the substrate.

9. The display panel according to claim 8, wherein the display panel further comprises a second initialization signal line, an orthographic projection of the second initialization signal line on the substrate is located on a side of an orthographic projection of the first gate of the driving transistor on the substrate away from an orthographic projection of the first scan signal line on the substrate;
the pixel circuit further comprises a second capacitor and a third transistor, a gate of the third transistor is located in the third conductive layer, the active layer further comprises a fourth active layer extending in the second direction, the fourth active layer is in the same layer as but is not connected to the third active layer, the second active layer and the first active layer, and a channel region of the third transistor is located in the fourth active layer;
the channel region of the third transistor is located at an orthographic projection of the gate of the third transistor on the fourth active layer, a first electrode of the third transistor is connected to the second initialization signal line via the first-type via, the fourth conductive layer further comprises a sixth connection line and a seventh connection line, a second electrode of the third transistor is connected to a first plate of the second capacitor via the sixth connection line, and a second plate of the second capacitor is connected to the second electrode of the driving transistor via the seventh connection line;
the second electrode of the third transistor is connected to one end of the sixth connection line via the first-type via, the first plate of the second capacitor is connected to the other end of the sixth connection line via the second-type via, the second plate of the second capacitor is connected to one end of the seventh connection line via the second-type via, and the second electrode of the driving transistor is connected to the other end of the seventh connection line via the first-type via;
an orthographic projection of the first plate of the second capacitor on the substrate at least partially covers an orthographic projection of the channel region of the third transistor on the substrate;
an orthographic projection of the fourth active layer on the substrate overlaps the orthographic projection of the second initialization signal line on the substrate;
at an intersection of the fourth active layer and the second initialization signal line, the first electrode of the third transistor is connected to the second initialization signal line via the first-type via;
the display panel further comprises a first light-emission control signal line, the first light-emission control signal line is located in the fourth conductive layer, and the first light-emission control signal line is connected to the gate of the third transistor via the first-type via;
the first light-emission control signal line intersects the gate of the third transistor, and at an intersection of the first light-emission control signal line and the gate of the third transistor, the first light-emission control signal line is connected to the gate of the third transistor via the first-type via;
the first light-emission control signal line extends in the first direction, and the second initialization signal line extends in the first direction;
the second initialization signal line is located in the fourth conductive layer; and
the first light-emission control signal line is located on a side of the second initialization signal line away from the first active layer.

10. The display panel according to claim 9, wherein the display panel further comprises a data line, the pixel circuit further comprises a fourth transistor, a gate of the fourth transistor is located in the third conductive layer, and a channel region of the fourth transistor is located in the fourth active layer;
the channel region of the fourth transistor is located at an orthographic projection of the gate of the fourth transistor on the fourth active layer, the fourth conductive layer further comprises an eighth connection line, a first electrode of the fourth transistor is connected to the data line via the eighth connection line, and a second electrode of the fourth transistor is connected to the second electrode of the third transistor via the fourth active layer;
the first electrode of the fourth transistor is connected to one end of the eighth connection line via the first-type via, and the data line is connected to the other end of the eighth connection line via a third-type via;
the display panel further comprises a second scan signal line, the second scan signal line is located in the fourth conductive layer, and the second scan signal line is connected to the gate of the fourth transistor via the first-type via;
the second scan signal line intersects the gate of the fourth transistor, and at an intersection of the second scan signal line and the gate of the fourth transistor, the second scan signal line is connected to the gate of the fourth transistor via the first-type via;
the first conductive layer further comprises a second light-shielding layer, the second light-shielding layer is in the same layer as but is not connected to the first light-shielding layer and the first plate of the first capacitor, and an orthographic projection of the second light-shielding layer on the substrate at least partially covers an orthographic projection of the channel region of the fourth transistor on the substrate;
the second light-shielding layer and the first plate of the second capacitor are in the same layer and are connected as an integrated structure;
the plurality of conductive layers further comprise a fifth conductive layer, the fifth conductive layer is located on a side of the fourth conductive layer away from the substrate, and the data line is located in the fifth conductive layer;
the second scan signal line extends in the first direction;
an orthographic projection of the first light-emission control signal line on the substrate is located between the orthographic projection of the second initialization signal line on the substrate and an orthographic projection of the second scan signal line on the substrate; and
in the second direction, the first light-emission control signal line, the second scan signal line and the second initialization signal line are located on the same side of the first active layer, and the first initialization signal line and the first scan signal line are located on the other side of the first active layer.

11. The display panel according to claim 9, wherein
the first plate of the second capacitor is located in the first conductive layer, and the second plate of the second capacitor is located in the second conductive layer;
an orthographic projection of the second plate of the second capacitor on the substrate at least partially overlaps the orthographic projection of the second initialization signal line on the substrate;
the second plate of the second capacitor comprises a main portion extending in the first direction and a branch portion extending in the second direction, an orthographic projection of the branch portion on the substrate overlaps the orthographic projection of the second initialization signal line on the substrate, and an orthographic projection of the main portion on the substrate is located between the orthographic projection of the second initialization signal line on the substrate and an orthographic projection of the first active layer on the substrate; and
the branch portion and the main portion are of an integrated structure.

12. The display panel according to claim 10, wherein the pixel circuit further comprises a fifth transistor, a gate of the fifth transistor is located in the third conductive layer, the active layer further comprises a fifth active layer, the fifth active layer is in the same layer as but is not connected to the fourth active layer, the third active layer, the second active layer and the first active layer, and a channel region of the fifth transistor is located in the fifth active layer;
the channel region of the fifth transistor is located at an orthographic projection of the gate of the fifth transistor on the fifth active layer, a second electrode of the fifth transistor is connected to the first electrode of the second transistor via a ninth connection line, a first electrode of the fifth transistor is connected to the second electrode of the second transistor via a tenth connection line, and the gate of the fifth transistor is connected to the second scan signal line via the first-type via;
the second scan signal line intersects the gate of the fifth transistor, and at an intersection of the second scan signal line and the gate of the fifth transistor, the gate of the fifth transistor is connected to the second scan signal line via the first-type via; and
the orthographic projection of the second light-shielding layer on the substrate at least partially covers an orthographic projection of the channel region of the fifth transistor on the substrate.

13. The display panel according to claim 12, wherein
the fourth conductive layer further comprises an eleventh connection line, a twelfth connection line, a thirteenth connection line and a fourteenth connection line, the second electrode of the fifth transistor is connected to one end of the eleventh connection line via the first-type via, the other end of the eleventh connection line is connected to one end of the ninth connection line via the third-type via, the other end of the ninth connection line is connected to one end of the twelfth connection line via the third-type via, and the other end of the twelfth connection line is connected to the first electrode of the second transistor via the first-type via;
the first electrode of the fifth transistor is connected to one end of the thirteenth connection line via the first-type via, the other end of the thirteenth connection line is connected to one end of the tenth connection line via the third-type via, the other end of the tenth connection line is connected to one end of the fourteenth connection line via the third-type via, and the other end of the fourteenth connection line is connected to the second electrode of the second transistor via the first-type via;
the ninth connection line and the tenth connection line are both located in the fifth conductive layer; and
the fifth active layer and the fourth active layer are located on the other side of the first active layer.

14. The display panel according to claim 13, wherein the first initialization signal line comprises a first sub-signal line extending in the first direction and a second sub-signal line extending in the second direction, and the first sub-signal line and the second sub-signal line are connected at at least one intersection to form a mesh structure;
the first sub-signal line and the second sub-signal line are disposed in different layers;
the first sub-signal line is located in the fourth conductive layer, and the second sub-signal line is located in the fifth conductive layer;
an orthographic projection of the first sub-signal line on the substrate is located on a side of the orthographic projection of the first scan signal line on the substrate away from the orthographic projection of the first gate of the driving transistor on the substrate; an orthographic projection of the second sub-signal line on the substrate covers orthographic projections of the channel regions of part of the transistors on the substrate; and
the second sub-signal line is multiplexed as the ninth connection line.

15. The display panel according to claim 13, wherein
the pixel circuit further comprises a sixth transistor and a seventh transistor, a gate of the sixth transistor and a gate of the seventh transistor are both located in the third conductive layer, a channel region of the sixth transistor is located in the second active layer, and a channel region of the seventh transistor is located in the fifth active layer;
the display panel further comprises a power line, the fourth conductive layer further comprises a fifteenth connection line, a second electrode of the sixth transistor is connected to the power line via the first-type via, and a first electrode of the sixth transistor is connected to the second electrode of the driving transistor via the fourth connection line; a second electrode of the seventh transistor is connected to the first electrode of the driving transistor via the fifteenth connection line, and a first electrode of the seventh transistor is connected to the thirteenth connection line;
the power line intersects the second active layer, and at an intersection of the power line and the second active layer, the second electrode of the sixth transistor is connected to the power line via the first-type via;
the first electrode of the sixth transistor is connected to one end of the fourth connection line via the first-type via, and the second electrode of the driving transistor is connected to the other end of the fourth connection line via the first-type via; the second electrode of the seventh transistor is connected to one end of the fifteenth connection line via the first-type via, the first electrode of the driving transistor is connected to the other end of the fifteenth connection line via the first-type via, and the first electrode of the seventh transistor is connected to the thirteenth connection line via the first-type via;
the display panel further comprises a second light-emission control signal line extending in the first direction, the orthographic projection of the first light-emission control signal line on the substrate and an orthographic projection of the second light-emission control signal line on the substrate are respectively located on two sides of an orthographic projection of the first active layer on the substrate;
the orthographic projection of the second light-emission control signal line on the substrate is located on a side of the orthographic projection of the first initialization signal line on the substrate away from the orthographic projection of the first scan signal line on the substrate;
the gate of the sixth transistor is connected to the second light-emission control signal line via the first-type via, and the gate of the seventh transistor is connected to the first light-emission control signal line via the first-type via;
the second light-emission control signal line intersects the gate of the sixth transistor, and at an intersection of the second light-emission control signal line and the gate of the sixth transistor, the gate of the sixth transistor is connected to the second light-emission control signal line via the first-type via;
the first light-emission control signal line intersects the gate of the seventh transistor, and at an intersection of the first light-emission control signal line and the gate of the seventh transistor, the gate of the seventh transistor is connected to the first light-emission control signal line via the first-type via;
an orthographic projection of the power line on the substrate is located on a side of the orthographic projection of the second light-emission control signal line on the substrate away from the orthographic projection of the first initialization signal line on the substrate;
the orthographic projection of the first light-shielding layer on the substrate at least partially covers an orthographic projection of the channel region of the sixth transistor on the substrate; and
the orthographic projection of the first plate of the second capacitor on the substrate at least partially covers an orthographic projection of the channel region of the seventh transistor on the substrate.

16. The display panel according to claim 15, wherein
the power line comprises a third sub-signal line extending in the first direction and a fourth sub-signal line extending in the second direction, the third sub-signal line and the fourth sub-signal line are located in different conductive layers, and the third sub-signal line and the fourth sub-signal line are connected at at least one intersection to form a mesh structure;
the second electrode of the sixth transistor is connected to the third sub-signal line via the first-type via;
an orthographic projection of the fourth sub-signal line on the substrate covers orthographic projections of the channel regions of part of the transistors on the substrate; and
the third sub-signal line is located in the fourth conductive layer, and the fourth sub-signal line is located in the fifth conductive layer.

17. The display panel according to claim 15, wherein the display panel further comprises light-emitting elements, each light-emitting element comprises a first electrode, a light-emitting functional layer and a second electrode that are stacked, and the first electrode is located on a side of the fifth conductive layer away from the substrate;
the first electrode is connected to one end of the tenth connection line via a fourth-type via; and
an orthographic projection of the first electrode on the substrate covers at least orthographic projections of the channel regions of part of the transistors on the substrate.

18. The display panel according to claim 17, further comprising:
a capacitor insulating layer located between the first conductive layer and the second conductive layer, an orthographic projection of the capacitor insulating layer on the substrate covering an orthographic projection of the first conductive layer on the substrate;
a first gate insulating layer located between the second conductive layer and the active layer, an orthographic projection of the first gate insulating layer on the substrate covering an orthographic projection of the second conductive layer on the substrate;
a second gate insulating layer located between the active layer and the third conductive layer, an orthographic projection of the second gate insulating layer on the substrate covering the orthographic projection of the active layer on the substrate;
an interlayer insulating layer located between the third conductive layer and the fourth conductive layer, an orthographic projection of the interlayer insulating layer on the substrate covering an orthographic projection of the third conductive layer on the substrate;
a first planarization layer located between the fourth conductive layer and the fifth conductive layer, an orthographic projection of the first planarization layer on the substrate covering an orthographic projection of the fourth conductive layer on the substrate; and
a second planarization layer located on the side of the fifth conductive layer away from the substrate, an orthographic projection of the second planarization layer on the substrate covering an orthographic projection of the fifth conductive layer on the substrate;
wherein the first-type via extends through the interlayer insulating layer, or the first-type via extends through the interlayer insulating layer and the second gate insulating layer;
the second-type via extends through the interlayer insulating layer, the second gate insulating layer, the first gate insulating layer, and the capacitor insulating layer;
the third-type via extends through the first planarization layer; and
the fourth-type via extends through the second planarization layer.

19. The display panel according to claim 1, wherein a material of the active layer comprises a metal oxide.

20. A display device, comprising:
a display panel, comprising:
a substrate;
a plurality of conductive layers stacked on a side of the substrate;
at least one pixel circuit comprising a driving transistor and a first capacitor;
wherein the plurality of conductive layers comprise a first conductive layer and a second conductive layer, the second conductive layer is located on a side of the first conductive layer away from the substrate, a first plate of the first capacitor is located in the first conductive layer, a second plate of the first capacitor is located in the second conductive layer, and the second plate of the first capacitor is connected to a first gate of the driving transistor; and
an active layer located on a side of the second conductive layer away from the substrate.
